(19) United States
(12) Patent Application Publication
(10) Pub. No.: US 2016/0345448 A1
(43) Pub. Date: Nov. 24, 2016

(54) REMOVABLE COVER FASTENING APPARATUS FOR ELECTRONIC DEVICES

(71) Applicant: CHEN-SHENG YANG, Kaohsiung (TW)

(72) Inventor: CHEN-SHENG YANG, Kaohsiung (TW)

(21) Appl. No.: 14/806,815

(22) Filed: Jul. 23, 2015

(30) Foreign Application Priority Data
May 18, 2015 (TW) 104115788

(51) Int. Cl. H05K 5/02; F16B 33/02; H05K 5/03

(52) U.S. Cl. CPC H05K 5/0208; H05K 5/03; H05K 5/0217; F16B 33/02

(57) ABSTRACT

A removable cover fastening apparatus for electronic devices has a housing, a removable cover, and a fastening element. The housing has a threaded hole. The removable cover is detachably mounted in the housing and has a connecting hole. The connecting hole has a threaded portion and a concave portion. The fastening element has a rod portion, and the rod portion has a first threaded section and a second threaded section. The first threaded section engages the threaded portion of the connecting hole, and the second threaded section engages the threaded hole of the housing. Users may rotate the fastening element until the threaded section is detached from the threaded hole, thereby the removable cover is detached from the housing, and the fastening element does not drop off from the removable cover.

### BACKGROUND OF THE INVENTION

1. Field of the Invention

The present invention relates to a fastening apparatus, and more particularly to a removable cover fastening apparatus for electronic devices that can be operated conveniently.

2. Description of Related Art

An electronic device such as a power supply for LEDs, a remote control, etc., has a housing and a screw hole, and needs to change batteries or consumable parts. The screw hole is formed in a surface of the housing. A removable cover is detachably mounted on the housing of the conventional electronic device, and the position of the removable cover is corresponding to a position of the batteries or the consumable parts. For a conventional fastening apparatus for an electronic device, the removable cover has a through hole. To avoid the removable cover separating from the housing of the electronic device, a tiny screw is mounted through the removable cover, and is mounted in the screw hole of the housing via the through hole of the removable cover, and this fastens the removable cover securely on the housing of the electronic device.

However, the tiny screw may drop off from the removable cover when the removable cover is detached by rotating the tiny screw in a reverse direction, such that the tiny screw may be lost. Additionally, the tiny screw needs to be aligned with and mounted through the through hole of the removable cover repeatedly when the removable cover is mounted in the housing again, so the conventional fastening apparatus is inconvenient in use.

To overcome the shortcomings of the conventional fastening apparatus, the present invention provides a removable cover fastening apparatus for electronic devices to mitigate or obviate the aforementioned problems.

### SUMMARY OF THE INVENTION

The main objective of the present invention is to provide a removable cover fastening apparatus for electronic devices that can be operated conveniently.

The removable cover fastening apparatus for electronic devices has a housing, a removable cover, and a fastening element. The housing has a threaded hole. The removable cover is detachably mounted in the housing and has a connecting hole. The connecting hole has a threaded portion and a concave portion. The fastening element has a rod portion, and the rod portion has a first threaded section and a second threaded section. The first threaded section engages with the threaded portion of the connecting hole, and the second threaded section engages the threaded hole of the housing. Users may rotate the fastening element until the threaded section is detached from the threaded hole, thereby the removable cover is detached from the housing, and the fastening element does not drop off from the removable cover.

Other objects, advantages, and novel features of the invention will become more apparent from the following detailed description when taken in conjunction with the accompanying drawing.

### BRIEF DESCRIPTION OF THE DRAWINGS

FIG. 1 is a perspective view of a removable cover fastening apparatus for electronic devices in accordance with the present invention;

FIG. 2 is an enlarged side view in partial section of the removable cover fastening apparatus in FIG. 1;

FIG. 3 is an enlarged perspective view of a fastening element of the removable cover fastening apparatus in FIG. 1;

FIG. 4 is a side view of the fastening element of the removable cover fastening apparatus in FIG. 3;

FIG. 5 is an enlarged and operational side view in partial section of the removable cover fastening apparatus in FIG. 2; and

FIG. 6 is another enlarged and operational side view in partial section of the removable cover fastening apparatus in FIG. 2.

### DETAILED DESCRIPTION OF PREFERRED EMBODIMENT

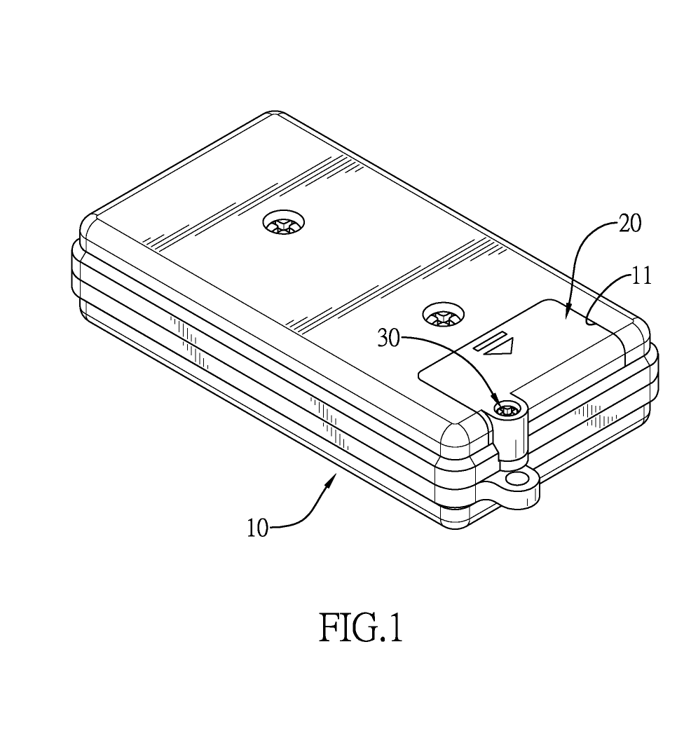

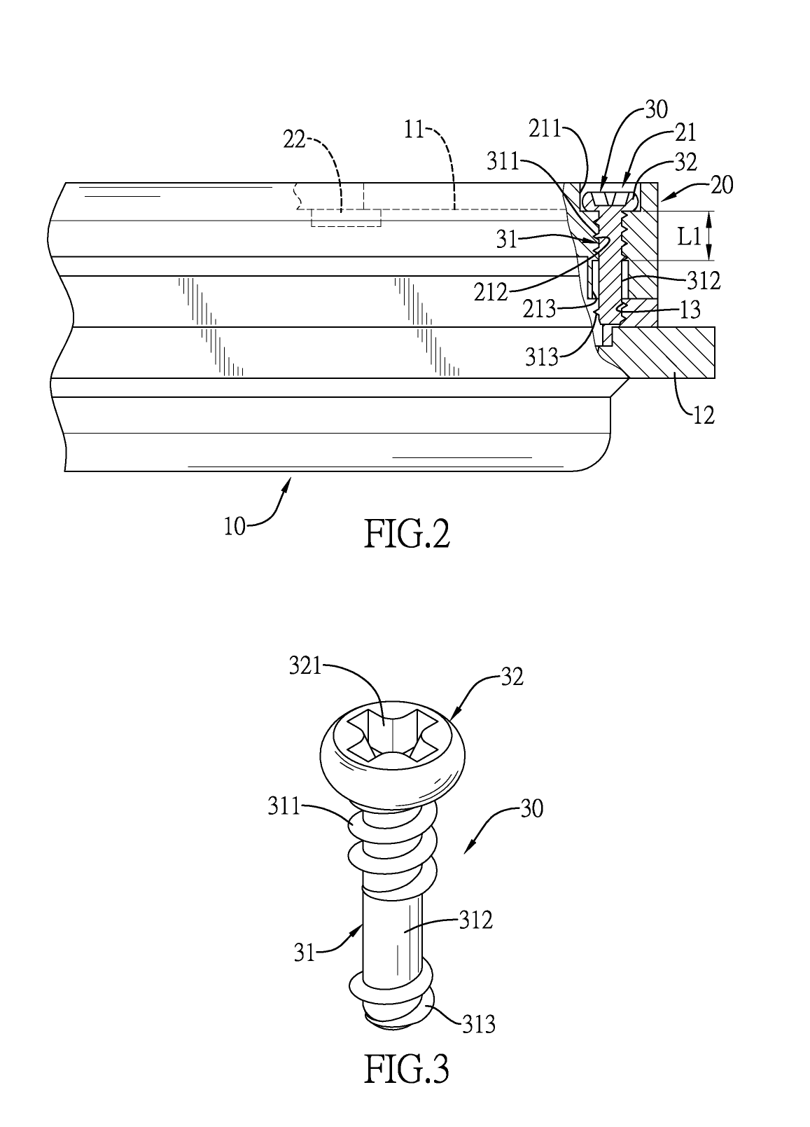

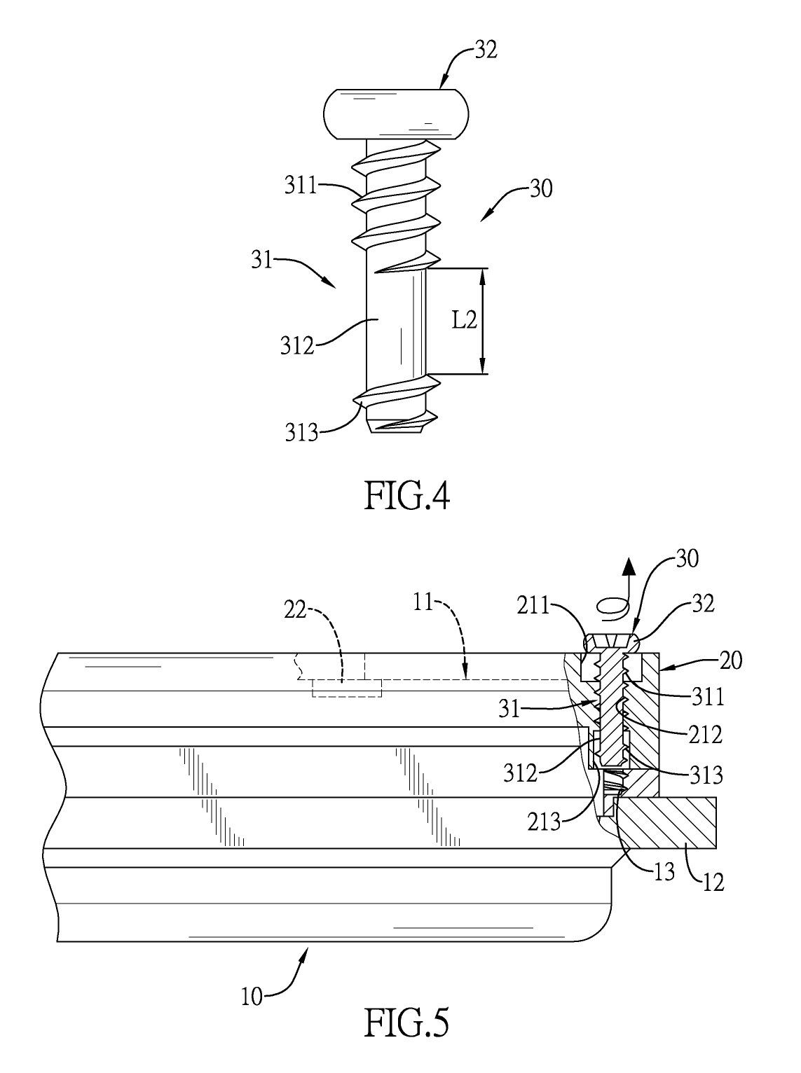

With reference to FIGS. 1 and 2, a removable cover fastening apparatus for electronic devices in accordance with the present invention comprises a housing 10, a removable cover 20, and a fastening element 30.

With reference to FIGS. 1 and 2, the housing 10 has a top surface, a side surface, a cover recess 11, a working portion 12, and a threaded hole 13. The housing 10 may contain circuit boards, batteries, and consumable parts of an electronic device. The cover recess 11 is concaved inward in the top surface of the housing 10 and corresponds in position to the batteries and the consumable parts. The working portion 12 is formed on and protrudes horizontally from the side surface and adjacent to the cover recess 11. The threaded hole 13 is formed in the housing 10 and adjacent to the side surface of the housing 10. The threaded hole 13 is formed in the housing 10 above the working portion 12 and has an inner diameter.

With reference to FIGS. 1 and 2, the removable cover 20 is detachably mounted in the cover recess 11 of the housing 10, abuts the working portion 12 of the housing 10, and has a top surface, a bottom surface, a connecting hole 21, and a fin 22.

The connecting hole 21 is formed in the removable cover 20 above the threaded hole 13 of the housing 10, and has a countersunk portion 211, a threaded portion 212, and a concave portion 213. The countersunk portion 211 is concaved inward in the top surface of the removable cover 20 and has an inner diameter. The threaded portion 212 is formed in the removable cover 20 below the countersunk portion 211, and has an inner diameter and a length (L1). The inner diameter of the threaded portion 212 is equal to the inner diameter of the threaded hole 13 of the housing 10. In addition, the inner diameter of the threaded portion 212 is smaller than the inner diameter of the countersunk portion 211. The concave portion 213 is formed in the removable cover 20 below the threaded portion 212 and has an inner diameter. The inner diameter of the concave portion 213 is larger than or equal to the inner diameter of the threaded portion 212.

The fin 22 is formed on the bottom surface of the removable cover 20 and protrudes away from the connecting hole 21, and the fin 22 abuts the cover recess 11.

With reference to FIGS. 1 to 3, the fastening element 30 is mounted through the removable cover 20, is mounted in the housing 10, and has a top, a bottom, a rod portion 31, and a head portion 32. The fastening element 30 detachably holds the removable cover 20 in the housing 10.

The rod portion 31 is formed on the bottom of the fastening element 30, is mounted through and engages the connecting hole 21, and is mounted in the threaded hole 13. The rod portion 31 has a top surface, a top, a middle, a bottom, a first threaded section 311, a straight rod section 312, and a second threaded section 313. The first threaded section 311 is formed on the top of the rod portion 31, is mounted through and engages with the threaded portion 212 of the connecting hole 21, and has an outer diameter. The outer diameter of the first threaded section 311 is equal to the inner diameter of the threaded hole 13.

The straight rod section 312 is formed on the middle of the rod portion 31 below the first threaded section 311, is mounted through the threaded portion 212 and in the concave portion 213 of the connecting hole 21, and has an outer diameter and a length (L2). The length (L2) of the straight rod section 312 is longer than or equal to the length (L1) of the threaded portion 212 of the connecting hole 21. The outer diameter of the straight rod section 312 is smaller than or equal to the outer diameter of the first threaded section 311. The second threaded section 313 is formed on the bottom of the rod portion 31 below the straight rod section 312, and has an outer diameter. The second threaded section 313 is mounted through the threaded portion 212 and the concave portion 213, and is mounted in the threaded hole 13 of the housing 10. The outer diameters of the second threaded section 313 and the first threaded section 311 are equal to the inner diameters of the threaded portion 212 and the threaded hole 13. The outer diameter of the straight rod section 312 is smaller than or equal to the outer diameters of the first threaded section 311 and the second threaded section 313. The outer diameter of the straight rod section 312 is smaller than or equal to the outer diameter of the second threaded section 313.

The head portion 32 is formed on the top of the fastening element 30, protrudes upwardly from the top surface of the rod portion 31, and is mounted in the countersunk portion 211 of the connecting hole 21. The head portion 32 of the fastening element 30 has a top surface and a joining recess 321. The head portion 32 of the fastening element 30 may be a circular or a polygonal block. When the head portion 32 is a polygonal block, the head portion 32 may be directly assembled with a rotating tool.

With reference to FIGS. 1 to 3, when the head portion 32 is a circular or polygonal block, the joining recess 321 is concaved downward in the top surface of the head portion 32. The joining recess 321 may be a slot recess, a cross recess or a polygonal recess. So the head portion 32 can be assembled with the rotating tool via the joining recess 321.

With reference to the FIGS. 1 to 3, when the fastening element 30 fastens the removable cover 20 with the housing 10, the removable cover 20 is mounted in the cover recess 11 of the housing 10. The position of the connecting hole 21 of the removable cover 20 is corresponding to the position of the threaded hole 13 of the housing 10, and the rod portion 31 of the fastening element 30 is mounted through and engages the threaded hole 13 of the housing 10, the threaded portion 212, and the concave portion 213. The first threaded section 311 of the rod portion 31 is mounted through and engages with the threaded portion 212 of the connecting hole 21. The straight rod section 312 of the rod portion 31 is mounted in the concave portion 213 of the connecting hole 21 via the countersunk portion 211 and threaded portion 212. The second threaded section 313 of the rod portion 31 is mounted through and engages the threaded hole 13 of the housing 10 via the countersunk portion 211, threaded portion 212, and concave portion 213. The head portion 32 of the fastening element 30 is mounted in the countersunk portion 211 of the connecting hole 21. So the fastening element 30 may fasten the removable cover 20 and the housing 10 together.

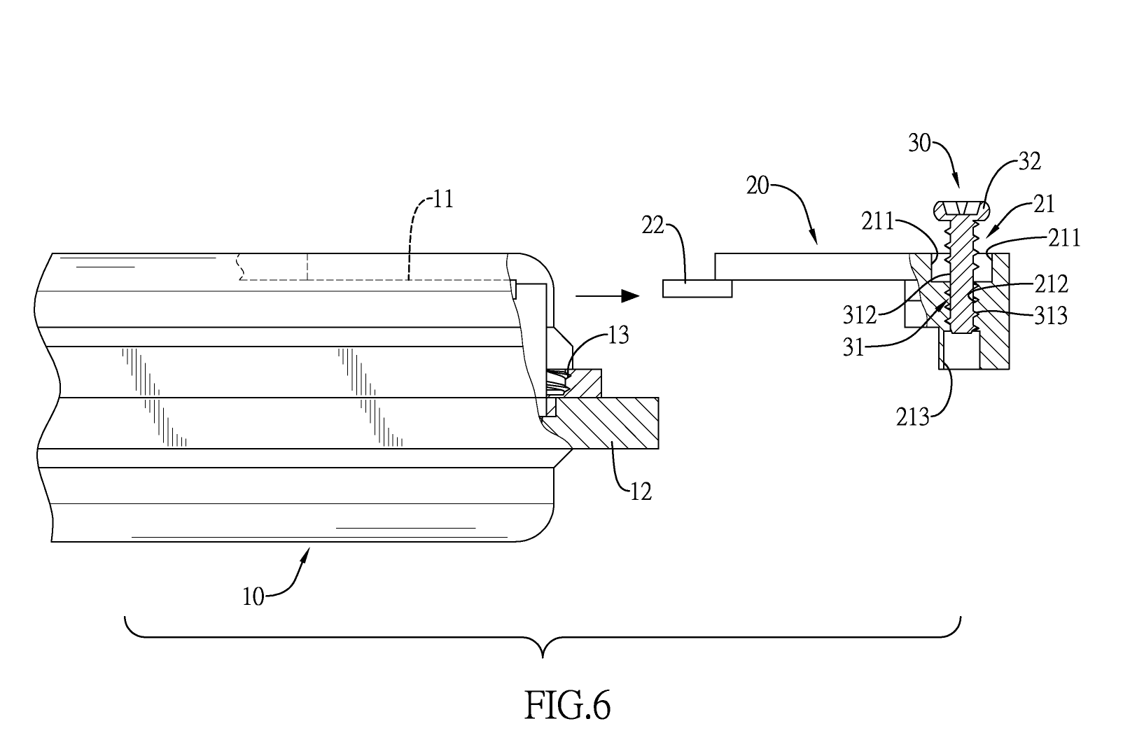

With reference to the FIGS. 5 and 6, when the removable cover 20 is detached from the housing 10, users may rotate the fastening element 30 in a reverse direction until the second threaded section 313 is detached from the threaded hole 13 of the housing 10. At the same time, the first threaded section 311 of the fastening element 30 is detached from the threaded portion 212 of the connecting hole 21 and moves upwardly to the countersunk portion 211 of the connecting hole 21, and the straight rod section 312 of the fastening element 30 moves to the countersunk portion 211 of the connecting hole 21 of the removable cover 20. The second threaded section 313 of the fastening element 30 moves to the concave portion 213 of the connecting hole 21. So the straight rod section 312 of the fastening element 30 is located in the threaded portion 212 of the connecting hole 21, and the first threaded section 311 and the second threaded section 313 of the fastening element 30 respectively disengage from the threaded hole 13 of the housing 10 and the threaded portion 212 of removable cover 20. Because the length (L2) of the straight rod section 312 is longer than or equal to the length (L1) of the threaded portion 212 of the connecting hole 21, even though the users over-rotate the fastening element 30 in a reverse direction, the fastening element 30 would remain idle in the connecting hole 21 of the removable cover 20, and this function makes the fastening element 30 always stay in the removable cover 20 without loosening, and the users may detach the removable cover 20 from the housing 10.

Furthermore, the users may apply an upward force on the fastening element 30 when rotating the fastening element 30 in a reverse direction. The second threaded section 313 of the fastening element 30 passes through the threaded portion 212 of the removable cover 20, such that the user may detach the fastening element 30 from the removable cover 20. Because the fastening element remains in the removable cover 20, users may rotate the fastening element 30 to quickly fasten the removable cover 20 on the housing 10 again.

The removable cover fastening apparatus for electronic devices as described has the following advantages.

1. As the fastening element 30 remains in the removable cover 20, the fastening element 30 does not drop off from the removable cover 20 when the removable cover 20 is detached from the housing 10. So the fastening element 30 is not loosened when the removable cover 20 is detached from the housing 10.

2. As the fastening element 30 remains in the removable cover 20, users may rotate the fastening element 30 to quickly fasten the removable cover 20 on the housing 10 again quickly, thereby making the position of the threaded hole 13 correspond in position to the fastening element 30 easily.

Even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A removable cover fastening apparatus for electronic devices comprising:
a housing having
a top surface;
a side surface;
a cover recess concaved inward in the top surface of the housing;
a working portion protruding from the side surface and adjacent to the cover recess; and
a threaded hole formed in the housing and adjacent to the side surface of the housing and above the working portion, the threaded hole having an inner diameter;
a removable cover detachably mounted in the cover recess of the housing, abutting the working portion of the housing, and having
a top surface;
a bottom surface; and
a connecting hole formed in the removable cover above the threaded hole of the housing and having
a threaded portion having
an inner diameter, wherein the inner diameter of the threaded portion is equal to the inner diameter of the threaded hole of the housing; and
a concave portion formed in the removable cover and below the threaded portion and having
an inner diameter, wherein the inner diameter of the concave portion is larger than or equal to the inner diameter of the threaded portion; and
a fastening element mounted through the removable cover and the housing and having
a top;
a bottom;
a rod portion formed on the bottom of the fastening element, mounted through and engaging the threaded hole and the connecting hole, and having
a top surface;
a top;
a middle;
a bottom;
a first threaded section formed on the top of the rod portion, mounted through and engaging with the threaded portion of the connecting hole, and having
an outer diameter, wherein the outer diameter of the first threaded section is equal to the inner diameter of the threaded hole;
a straight rod section mounted through the concave portion of the connecting hole, the straight rod section formed on the middle of the rod portion and adjacent to the first threaded section, and having
an outer diameter, wherein the outer diameter of the straight rod section is smaller than or equal to the outer diameter of the first threaded section; and
a second threaded section formed on the bottom of the rod portion below the straight rod section, the second threaded section mounted through and engaging the threaded hole of the housing and having
an outer diameter, wherein the outer diameters of the second threaded section and the first threaded section are equal to the inner diameter of the threaded hole, and the outer diameter of the straight rod section is smaller than or equal to the outer diameter of the second threaded section; and
a head portion formed on the top of the fastening element and protruding upwardly from the top surface of the rod portion.

2. The removable cover fastening apparatus for electronic devices as claimed in claim 1, wherein
the connecting hole of the removable cover has a countersunk portion concaved inward in the top surface of the removable cover; and
the head portion of the fastening element is mounted in the countersunk portion of the connecting hole.

3. The removable cover fastening apparatus for electronic devices as claimed in claim 1, wherein the head portion has a joining recess concaved downward in a top surface of the head portion.

4. The removable cover fastening apparatus for electronic devices as claimed in claim 2, wherein the head portion has a joining recess concaved downward in a top surface of the head portion.
